(19) United States
(12) Patent Application Publication
(10) Pub. No.: US 2025/0389309 A1
(43) Pub. Date: Dec. 25, 2025

(54) SENSORISED BRAKING DEVICE FOR A VEHICLE

(71) Applicant: ITT ITALIA S.R.L., Lainate (Milano) (IT)

(72) Inventors: Gianmaria MILANI, Candiolo (Torino) (IT); Stefano SERRA, Saluzzo (Cuneo) (IT); Marco TERRANOVA, Torino (IT); Cesare ZANGARI, Pinerolo (Torino) (IT)

(21) Appl. No.: 18/992,939

(22) PCT Filed: Jun. 28, 2023
(86) PCT No.: PCT/EP2023/067582

§ 371 Date: Jan. 9, 2025

(30) Foreign Application Priority Data
Jul. 15, 2022 (IT) 102022000014971

(51) Int. Cl. F16D 66/00; F16D 65/092; G01L 5/167

(52) U.S. Cl. CPC F16D 66/00; F16D 65/092; G01L 5/167; F16D 2066/005; F16D 2066/006

(57) ABSTRACT

Braking device for a vehicle, with a piezoelectric sensor (2) comprising: a piezoelectric material, two electrodes (6, 7), wherein the piezoelectric material comprises a first flat face (4) and a second flat face (5), the faces extending in parallel planes identified by two orthogonal y and z directions, wherein an electrical signal is collected by the electrodes when the piezoelectric material is simultaneously subjected to a normal force in an x-direction and to a shear force in the z-direction, wherein the first electrode is positioned on the first face and the second electrode is positioned on the second face and has extensions (7a, 7b) on the first face separated by the first electrode, wherein each of said extensions extends on a corresponding side of said first face, and wherein each of said extensions is symmetrically configured with respect to a central axis of the first face.

### CAMP

The following disclosure concerns a sensorised braking device for a vehicle, a piezoelectric shear force detection sensor, and a shear force detection method.

### SUMMARY

Piezoelectricity is the property of certain materials to polarise, generating a build-up of electrical charge, and thus a potential difference, when mechanically stressed.

Similarly, the opposite effect can occur, i.e. generating a deformation in the material by subjecting it to an electrical voltage, in which case we speak of an inverse piezoelectric effect. Piezoelectric materials include quartz crystals, tourmaline and Rochelle salt, they exhibit a relatively small piezoelectric response to external stresses that is not optimal for some applications such as the one under consideration.

To overcome this problem, some polycrystalline ferroelectric ceramics are synthesised, such as barium titanate (BaTiO3) and lead zirconate titanate (PZT), in such a way that the synthesised ceramics exhibit more pronounced piezoelectric properties, i.e. higher electrical voltages at the same mechanical stress or larger displacements when electrically stressed.

To impart piezoelectric properties to piezoceramic materials, they must undergo the polarisation procedure.

To this end, a strong electric field of several kV/mm is applied to create an asymmetry in the ceramic compound, which previously appeared to have randomly oriented domains and thus no net polarisation.

The application of an external electric field causes a rearrangement of the material's dipoles, which align parallel to its direction, making the total electric dipole no longer zero, as a result of which the material becomes polarised.

After polarisation, most reorientations are retained even without the application of an electric field until the material is brought to a temperature above the so-called Curie Temperature (TC), which is characteristic of the material.

At temperatures below TC, the lattice structure of PZT crystallites, for example, can distort due to external mechanical stress, causing a change in the overall polarisation.

This is therefore the mechanism of interest for piezoelectric technology. At temperatures above TC, the piezoceramic material loses its asymmetry within the lattice, causing the loss of its piezoelectric properties.

Following sintering and polarisation, the piezoceramic material is very hard and high-density and can be sawn and machined if necessary.

The compacted materials come in different shapes such as discs, plates, bars and cylinders. The last stage of the manufacturing process involves the deposition of electrodes. The electrodes are applied to the piezoceramic material by screen printing technology, sputtering or PVD (sputtering) and subsequently baked.

The thickness of conductive material can vary from 1 μm to 10 μm depending on the final application of the sensor.

The way the electrodes are geometrically arranged identifies 2 different types of sensors: with the electrodes on 2 opposing faces or with both contacts on the same face of the piezoceramic.

The latter is called a Wrapped Around Electrode (WAC) because one of the two electrodes wraps around a perimeter edge of the piezoelectric material to lie on the same face as the other electrode.

Polarised piezoelectric materials are characterised by various coefficients and relationships.

In simplified form, the basic relationships between electrical and elastic properties can be represented as follows:

$$D = d \cdot T + {ε}^{T} \cdot E$$

$$S = {S}^{E} \cdot T + d \cdot E$$

where D is the electric flux density, T the mechanical stress, E the electric field, S the mechanical stress, d the piezoelectric charge coefficient, ε^{T} the permectivity and SE the elasticity coefficient.

These relationships apply to small electrical and mechanical amplitudes, or so-called small signal values. In this range, the relationships between mechanical deformation, elastic S or stress T, and electric field E or electric flux density D are linear, and the values for the coefficients are constant.

As shown in FIG. 1, the directions are designated by 1, 2, and 3, corresponding to the X, Y, and Z axes of the classical set of orthogonal axes to the right.

Rotational axes are designated with 4, 5 and 6.

The polarisation direction (axis 3) is established during the polarisation process by a strong electric field applied between the two electrodes and typically above a certain critical value that depends on the piezoelectric material considered.

A fundamental characteristic parameter of a piezoelectric material is that the coupling between the mechanical deformation in a certain direction j and the potential generated on the faces in direction i is governed by the d coefficientsᵢⱼ, grouped in the d matrix:

$$d = ( \begin{matrix}{d}_{11} & {d}_{12} & {d}_{13} & {d}_{14} & {d}_{15} & {d}_{16} \\ {d}_{12} & {d}_{22} & {d}_{23} & {d}_{24} & {d}_{25} & {d}_{26} \\ {d}_{13} & {d}_{23} & {d}_{33} & {d}_{34} & {d}_{35} & {d}_{36} \\ {d}_{14} & {d}_{24} & {d}_{34} & {d}_{44} & {d}_{45} & {d}_{46} \\ {d}_{15} & {d}_{25} & {d}_{35} & {d}_{45} & {d}_{55} & {d}_{56} \\ {d}_{16} & {d}_{26} & {d}_{36} & {d}_{46} & {d}_{56} & {d}_{66}\end{matrix} )$$

Typically, piezoelectric sensors used in compressive or tractive force measurements are polarised in such a way that their polarisation axis agrees with the direction of mechanical deformation to be measured (z-axis, 3), while charges are collected from the faces orthogonal to this direction (faces 3).

The result is that the response to a sensor compression is governed by the coefficient d₃₃.

With similar reasoning, it can therefore be deduced that the sensors used in shear stress measurements, i.e. where there is relative creep between two opposing faces, are primarily governed by the coefficient d₁₅ (1 surfaces orthogonal to the x-axis, 5 shear deformation along the z-axis, polarisation).

When mechanical deformations are not perfectly unidirectional, the other coefficients may introduce a contribution to the final signal, sometimes even generating uncontrollable or destructive effects as we shall see later in the case of sensors with reported electrodes.

A sensorised braking device for a vehicle, in particular but not limited to a smart brake pad, is a braking device configured (e.g. with a suitable hardware and software system architecture and some algorithms) to measure one or more parameters, such as brake pad temperature and/or static and dynamic quantities including normal and shear forces applied during braking.

A shear force detection sensor may comprise a piezoelectric material plate having a main lying plane defined by orthogonal y and z directions, a thickness defined by an x direction orthogonal to the main lying plane yz, polarisation according to the z direction, and configured to collect electrical charges on faces parallel to the main lying plane yz.

A limitation of the peculiarities described above lies in the fact that, when used to read the shear force signal, the electrodes also pick up a significant amount of charges produced in the normal direction, which can complicate the correct interpretation of the signal to some extent; this phenomenon is called ‘cross talk’.

‘Cross talk’ consists of an electrical signal generated by the shear force sensor when a force is applied solely in the x-direction.

‘Cross talk’ is a phenomenon present in every piezoelectric component, however some types of piezoelectric shear sensors are affected to a greater extent, such as reported electrode sensors.

Particularly if the piezoelectric shear sensor is integrated into a braking device in which the shear force is always associated with a normal force during braking, ‘cross talk’ can make measurements unreliable and non-repeatable.

In the case of a sensorised brake pad, reported electrode sensors are the optimal solution for a large-scale production process, but they are also the most sensitive to ‘cross talk’ if not properly designed and manufactured.

If shear force sensors of this type are integrated into the two brake pads that make up a disc brake, completely different reading signals are obtained from the two shear force sensors as the ‘cross talk’ signal makes a variable contribution that can be either concordant or discordant to the signal that would be generated by a pure shear force.

Industrially (high volumes and low costs), the use of the reported electrode sensor is preferred, but if not properly designed, this leads to it being inappropriate for use in brake pads.

IT 1020210021017 filed by the same applicant illustrates a sensorised braking device for a vehicle, a piezoelectric shear force detection sensor, and a shear force detection method.

The technical task of the present invention is to remedy the drawbacks complained of by the known technique.

Within the scope of this technical task, one purpose of the invention is to provide a shear force sensor and a sensorised braking device integrating such a shear force sensor that produce reliable and repeatable measurements when the shear force sensor is simultaneously subjected to a shear force and a normal force.

Another purpose of the invention is to provide a shear force sensor and a sensorised braking device integrating such a shear force sensor that can be easily industrialised and produce reliable and repeatable measurements when the shear force sensor is subjected to a shear force and a normal force simultaneously.

The technical task, as well as this and other purposes, are achieved according to the invention by a sensorized braking device for a vehicle, comprising: at least one piezoelectric shear force sensing sensor, an electrical circuit configured to collect signals from said at least one sensor, wherein said sensor comprises: a piezoelectric material, a first and at least one second reading electrode, wherein said piezoelectric material includes a first flat face and a second flat face opposite said first flat face, said first and second flat faces extending in parallel planes identified by two orthogonal y and z directions, wherein said piezoelectric material has an axis of polarisation in said z direction, and wherein an electrical signal can be collected by said reading electrodes when said piezoelectric material is simultaneously subjected to a normal force in an x direction orthogonal to said two y and z directions and to said shear force in said z direction, said first electrode being positioned on said first plane face, and said second electrode being positioned on said second plane face and having one or more extensions on said first plane face separated from said first electrode, wherein each extension of said one or more extensions extends from a corresponding side of said first plane face, characterised in that each of said one or more extensions of said second electrode on said first plane face of said piezoelectric material is symmetrically configured with respect to a central axis of said first plane face of said piezoelectric material oriented along said y-direction.

Advantageously, the first electrode is also configured symmetrically with respect to a central axis of said first flat face of said piezoelectric material oriented along said y-direction.

In a preferred embodiment, the sensorised braking device for a vehicle comprises a brake pad comprising a backing plate and a block of friction material, wherein said electrical circuit is interposed between said backing plate and said block of friction material and said at least one sensor is interposed between said electrical circuit and said block of friction material.

The present invention also discloses a piezoelectric shear force sensing sensor, comprising a piezoelectric material, a first and at least one second readout electrode, wherein said piezoelectric material comprises a first flat face and a second flat face opposite said first flat face, said first and second flat faces extending in parallel planes identified by two orthogonal y and z directions, wherein said piezoelectric material has an axis of polarisation in said z direction, and wherein an electrical signal can be collected by said reading electrodes when said piezoelectric material is simultaneously subjected to a normal force in an x direction orthogonal to said two y and z directions and to said shear force in said z direction, said first electrode being positioned on said first face and said second electrode being positioned on said second face and having one or more extensions on said first face separated from said first electrode, wherein each of said one or more extensions of said one or more extensions extends from a corresponding side of said first plane face characterised by the fact that each of said one or more extensions of said second electrode present on said first face of said piezoelectric material is symmetrically configured with respect to a central axis of said first face of said piezoelectric material oriented along said y direction.

Finally, the present invention discloses a shear force sensing method with a sensorised braking device for a vehicle, comprising:
at least one piezoelectric shear force sensing sensor; an electrical circuit configured to collect signals from said at least one sensor; wherein said sensor comprises: a piezoelectric material, a first and at least one second readout electrode, wherein said piezoelectric material includes a first flat face and a second flat face opposite said first flat face, said first and second flat faces extending in parallel planes identified by two orthogonal directions y and z, wherein said piezoelectric material is polarized in said z direction, wherein said first electrode is positioned on said first face and said second electrode is positioned on said second face, wherein said second electrode is prolonged on said first face by one or more extensions separated from said first electrode, wherein each of said one or more extensions of said second electrode is prolonged on a corresponding side of said first plane face characterised by the fact of configuring each of said one or more extensions of said second electrode on said first face of said piezoelectric material symmetrically with respect to a central axis of said first face of said piezoelectric material oriented along said y direction.

### BRIEF DESCRIPTION OF THE DRAWINGS

Various forms of realisation are depicted in the attached drawings for illustrative purposes and should in no way be construed as limiting the scope of this disclosure.

Various peculiarities of the different forms of realisation disclosed can be combined to form additional forms of realisation, which are part of this disclosure.

FIG. 1 schematically illustrates an orthogonal coordinate system to describe the properties of a polarised piezoelectric material;

FIG. 2 shows schematically in side elevation a sensor-supported braking device for shear force detection;

FIG. 2a shows the braking device schematically in plan view;

FIGS. 3a and 3b show schematically in axonometry and plan view respectively a first way of realising the shear force sensor integrated in the braking device of FIG. 2, where the second electrode provides an extension;

FIG. 3c shows an AA section of the shear force sensor in FIGS. 3a and 3b;

FIGS. 4a and 4b show schematically in axonometry and plan view respectively a second way of realising the shear force sensor integrated in the brake device of FIG. 2, where the second electrode has two extensions;

FIG. 4c shows an AA section of the shear force sensor in FIGS. 4a and 4b;

FIG. 5 shows a finite-element model evaluating the effect of a combination of normal and shear forces on a force sensor with a reported electrode (WAC) attached to a metal plate, constrained at the edges and free to deform;

FIG. 6 shows strain vectors in the y-z plane of a force sensor with a reported electrode (WAC) attached to a metal plate respectively symmetrical with respect to the z-axis and with respect to the y-axis;

FIG. 7 shows the different resultant of the strain vectors in the y-z plane of a force sensor with a reported electrode (WAC) attached to a metal plate respectively symmetrical with respect to the z-axis and with respect to the y-axis;

### DETAILED DESCRIPTION

In the following detailed description, reference is made to the attached drawings, which form a related part.

In drawings, similar reference numbers typically identify similar components, unless the context indicates otherwise.

The illustrative forms of realisation described in the detailed description and drawings are not intended to be limiting.

Other forms of realisation may be used, and other changes may be made without departing from the spirit or scope of the subject matter presented here.

Aspects of the present disclosure, as generally described herein, and illustrated in the figures, may be arranged, substituted, combined, and designed in a wide variety of different configurations, all of which are explicitly contemplated and formed part of this description.

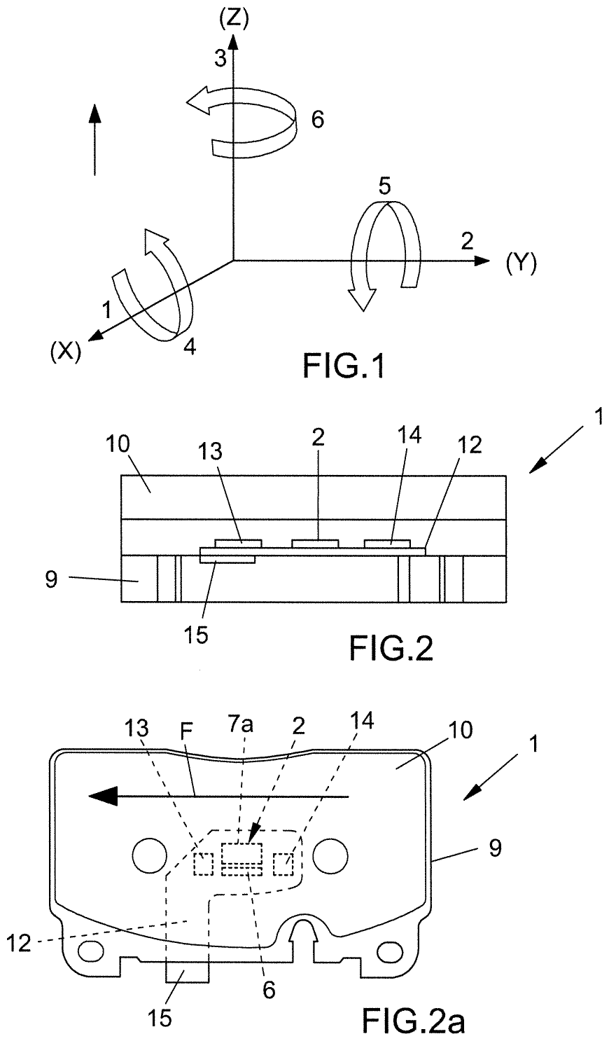

Referring to FIGS. 1 to 4c, the sensorised braking device 1 for shear force sensing comprises a piezoelectric shear force sensor 2 comprising a piezoelectric material 3, for example a sheet of piezoelectric material 3, having a first main flat face 4 and a second main flat face 5 opposite the first main flat face 4.

The first main plane face 4 and the second main plane face 5 extend in parallel planes identified by two orthogonal y and z directions.

Piezoelectric material 3 is electrically polarised with an electric vector field P, in the z-direction, which also identifies the direction of shear stress S of piezoelectric material 3.

As shown in the drawings, the z-direction is the direction along which the typically parallelepiped piezoelectric material 3 has the greatest length.

On the first main face 4 of the piezoelectric material 3, at least a first reading electrode 6 is placed.

At least a second reading electrode 7 is placed on the second main face 5 of the piezoelectric material 3.

The electrical signal is collected by electrodes 6, 7 when, in a braking event, the piezoelectric material 3 is simultaneously subjected to a normal force in the x-direction orthogonal to the two y- and z-directions and to the shear force in the z-direction.

Advantageously, the second electrode 7 has at least one extension 7a, 7e separated from the first electrode 6.

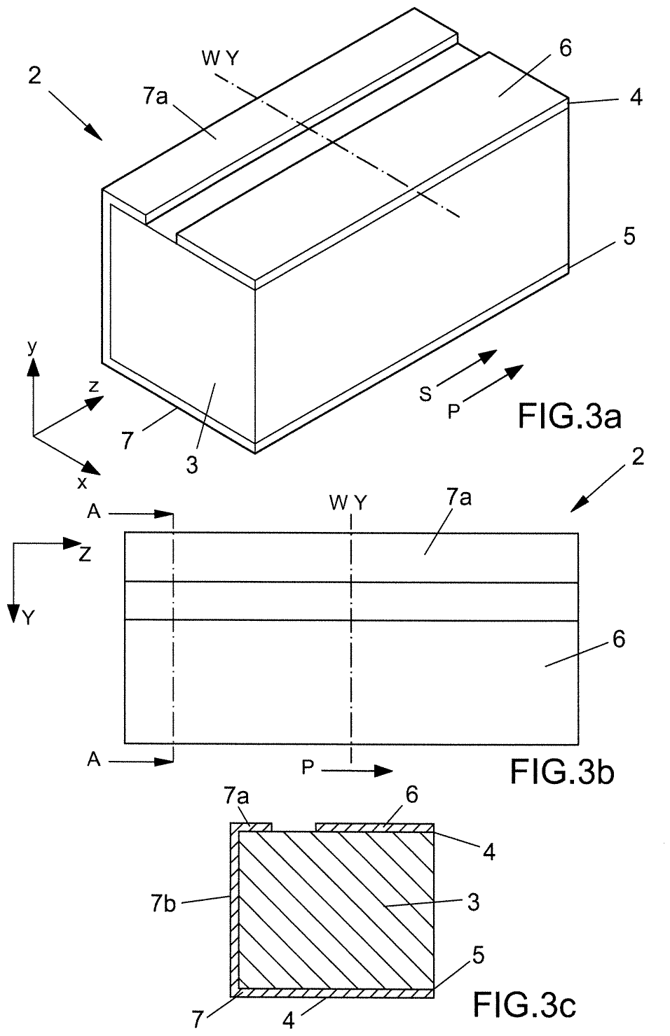

In accordance with a first preferred embodiment of the present invention illustrated in FIGS. 3a-3c, the force sensor 2 provides for a single extension 7a.

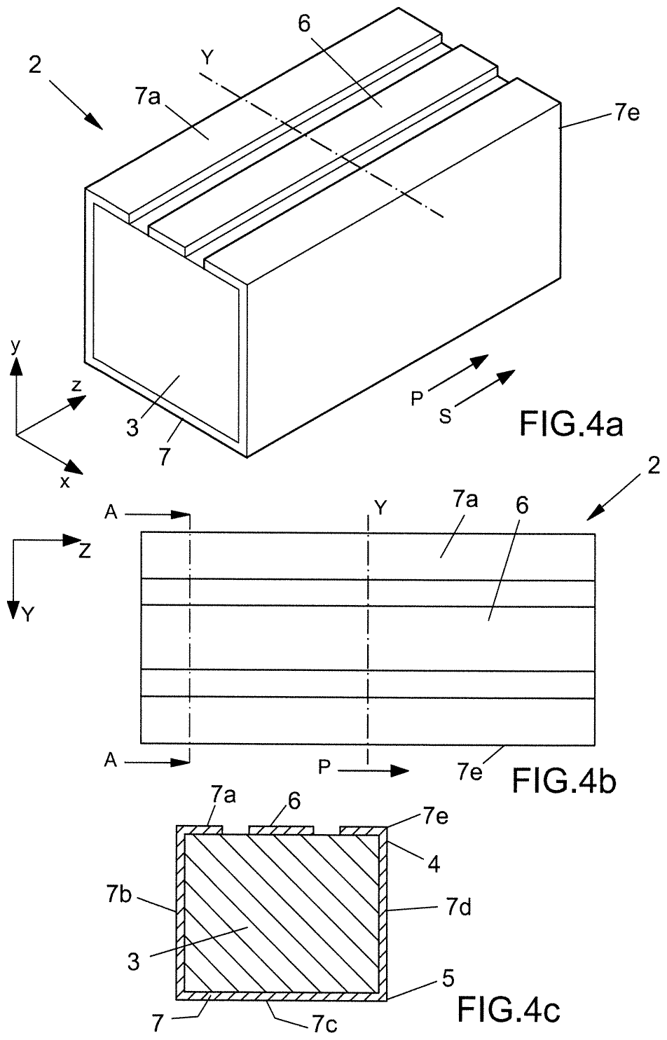

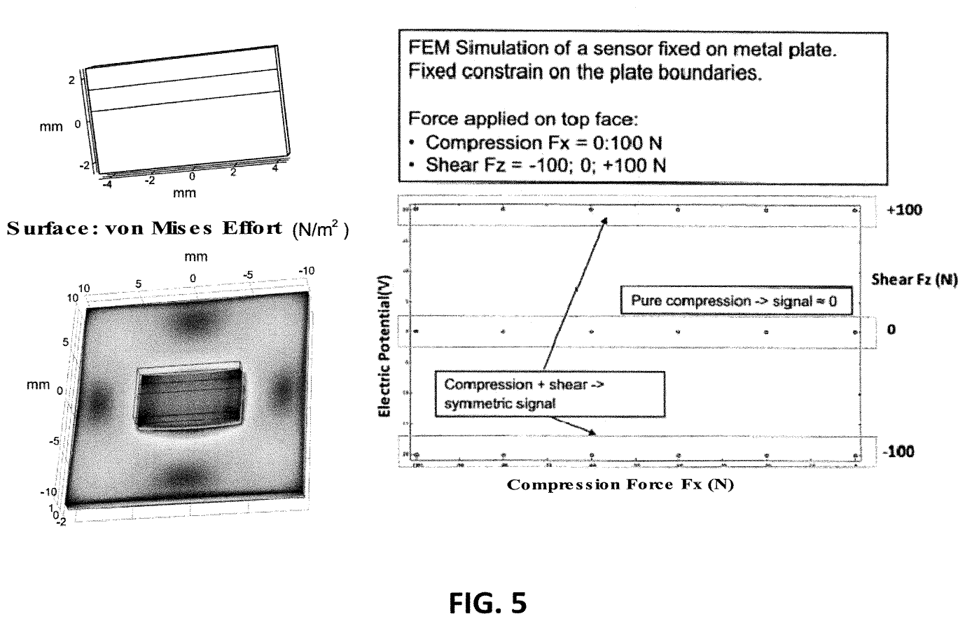

According to a second preferred form of execution illustrated in FIGS. 4a-4c, force sensor 2 has two extensions, 7a, 7e respectively.

Preferably, the piezoelectric material 3 has a parallelepiped quadrangular configuration, with the longest side developing longitudinally in the z-direction, parallel to the polarisation vector P.

In practice, with reference to the first preferred embodiment illustrated in FIGS. 3a-3c, the second reading electrode 7 comprises a first section 7c arranged on the second flat face 5 of the piezoelectric material 3, a second section 7b folded from the first section 7c and arranged along a perimeter edge of the piezoelectric material 3, a third section 7 a folded from the second section 7b arranged along the first flat face 4 of the piezoelectric material 3, and extending from the corresponding side of the flat face 4.

With reference to the second preferred embodiment illustrated in FIGS. 4 a-4c, the second reading electrode 7 comprises a first section 7c arranged on the second flat face 5 of the piezoelectric material 3, a second section 7b and a third opposing section 7d folded from the first section 7c and disposed along opposite perimeter edges of the piezoelectric material 3, a fourth 7a and a fifth opposite sections 7e folded from the second 7b and third 7d sections, and disposed along the first flat face 4 of the piezoelectric material 3 to define the opposite extensions 7a, 7e, extending from the corresponding sides of the flat face 4.

Advantageously, the two opposite extensions 7a, 7e of the second reading electrode 7 extend along opposite edges of the piezoelectric material 3 from a corresponding side of the first flat face 4.

Appropriately, the first electrode 6 is separated from the extensions 7a and 7e of the second electrode 7.

Advantageously, the opposite extensions 7a, 7e of the second reading electrode 7 are arranged and configured symmetrically with respect to the central Y-symmetry axis of the flat face 4 of the piezoelectric material 3, oriented along the y-direction.

Advantageously, the first electrode 6 is also arranged and configured symmetrically with respect to the central Y-symmetry axis of the flat face 4 of the piezoelectric material 3.

Piezoceramic material 3 can be either a screen-printed layer or a discrete element.

Piezoelectric material can include synthesised polycrystalline ferroelectric ceramic material, such as barium titanate (BaTiO3) and lead zirconate titanate (PZT).

The piezoelectric material in the present disclosure is not limited to synthesised ceramics and may include other types of ferroelectric material.

Each reading electrode 6, 7 can also consist of a layer deposited by screen-printing or sputtering on the piezoelectric material 3.

In certain embodiments, the reading electrodes 6, 7 may be formed from a screen printing layer of metallic material, such as silver, gold, copper, nickel, palladium. In a certain embodiment, the reading electrodes 6, 7 may be formed from silver ink or paste.

In some designs, one or more of the electrodes 6, 7 may be partially or completely covered by a protective material, such as a layer of insulation glass or ceramic to electrically and thermally insulate the electrodes and prevent oxidation.

In other solutions, the reading electrodes are also discrete elements.

With reference to the invention and illustrated in FIG. 2, the sensorised braking device 1 may comprise an intelligent brake pad.

An intelligent brake pad is a sensorised brake pad configured (e.g. with a suitable hardware and software system architecture and some algorithms) to measure one or more parameters, such as brake pad temperature and/or static and dynamic quantities including normal and shear forces applied during braking.

The brake pad comprises a backing plate 9, a block of friction material 10, and an electrical circuit 12 equipped with at least one shear sensor 2 of a type according to the present disclosure and preferably also at least one other sensor 13, 14 for example a normal force sensor and/or a temperature sensor.

Normal force sensors can comprise piezoceramic sensors, but alternatively they can also be capacitive or piezoresistive sensors.

Temperature sensors can be thermistors, e.g. PT1000, PT200 or PT100.

The electrical circuit 12 has electrical terminals arranged in a region 15 to collect signals from the brake pad.

The support plate 9, preferably but not necessarily made of metal, directly supports the electrical circuit 12.

The friction material block 10 is applied on the side of the carrier plate 9 where the electrical circuit 12 is located, the electrical circuit 12 is therefore embedded between the carrier plate 9 and the friction material block 10.

In some designs, as illustrated, the brake pad also includes a damping layer 16 that encompasses the sensors 2, 13, 14 and is interposed between the electrical circuit 12 and the friction material block 10.

The intelligent braking device can include a limited number of sensors in order to limit the number of operations and the power budget of the electronics so that it is also suitable for a wireless system for an on-board application.

During use, the brake pad may be capable of transmitting an electrical signal proportional to the braking forces applied to the brake pad as a result of contact with the element being braked, e.g. a disc of braking device 1.

The cutting sensor can preferably have at least 0.2 mm thickness of the piezoelectric material sheet with an operating temperature higher than 200° C.

In various designs, the shear force sensor allows measurement of wear, residual resistance and/or braking torque.

The electrical circuit 12 on which the sensors 2, 13, 14 are installed is electrically insulated. The electrical circuit 12 has branches suitably shaped to arrange the sensors 2, 13, 14 in separate positions on the support plate 12.

The electrical circuit 12 can be a screen-printed circuit.

In support of the invention, experimental tests performed on conventional WAC force sensors comparing a reported electrode not arranged symmetrically with respect to the Y-axis with a reported electrode arranged symmetrically with respect to the Y-axis are provided below.

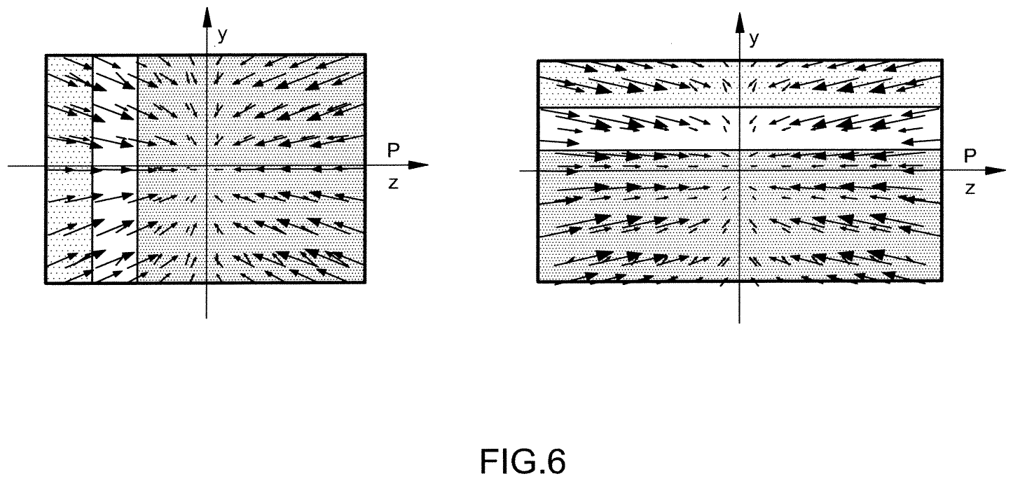

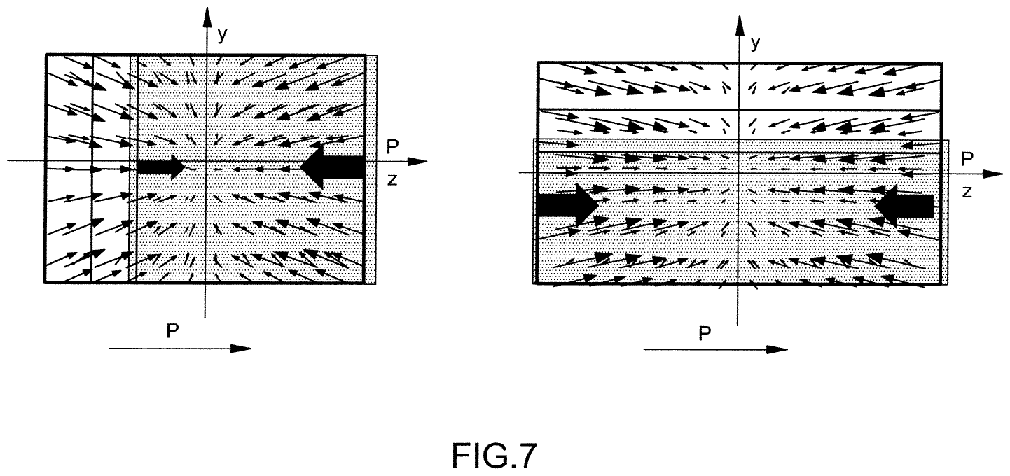

From FIG. 6 and in particular 7, the different resultant strain vectors in the y-z plane of a force sensor with a reported electrode (WAC) attached to a metal plate, respectively symmetrical with respect to the z-axis and with respect to the y-axis, is clearly evident.

In the case of symmetry with respect to the z-axis, the resultant force in the direction of the polarisation axis P differs from zero, and thus there is a significant cross-talk effect.

Advantageously, in the case of symmetry with respect to the Y-axis, the resultant force in the direction of the polarisation axis P is zero, and thus there is no cross-talk effect.

As shown in FIG. 2a, sensor 2 must be positioned in the correct orientation in braking device 1, particularly the polarisation axis P must be parallel to the direction of the shear force acting on the braking device, which is indicated by the arrow F.

The arrow F indicates the direction from right to left of the shear stresses, but obviously the shear stresses can operate in the opposite direction.

The scope of this disclosure is not to be limited by the particular forms of realisation disclosed above, but is only to be determined by a fair reading of the following claims as well as their full scope of equivalents.

1. A sensorised braking device for a vehicle, the sensorized braking device comprising:
a brake pad comprising a backing plate;
a block of friction material; and
an electrical circuit equipped with at least one piezoelectric sensor for detecting the shear force, said electric circuit being configured to receive signals from said at least one sensor, wherein said sensor comprises: a piezoelectric material, a first and at least a second reading electrode, wherein said piezoelectric material comprises a first flat face and a second flat face opposite the first flat face, the first and second flat face extending in parallel planes identified by two orthogonal directions y and z, wherein said piezoelectric material has a polarisation axis (P) in said direction z and wherein an electric signal can be received by said reading electrodes when said piezoelectric material is subjected simultaneously to a normal force in a direction x orthogonal to the two directions y and z and to said shear force in said direction z, said first electrode being positioned on said first flat face and said second electrode being positioned on said second flat face and having one or more extensions on said first flat face separated from said first electrode, wherein each extension of said one or more extensions extends from a corresponding side of said first flat face, wherein each of said one or more extensions of said second electrode present on said first flat face of said piezoelectric material is configured symmetrically relative to a central axis (Y) of said first flat face of said piezoelectric material oriented along said direction y.

2. The sensorised braking device for a vehicle according to claim 1, wherein the sensor is positioned with the orientation of said polarisation axis (P) parallel to the direction (F) of said shear force.

3. The sensorised braking device for a vehicle according to claim 1, wherein the first electrode is configured symmetrically relative to said central axis (Y) of said first flat face of said piezoelectric material.

4. The sensorised braking device for a vehicle according to claim 1, wherein the piezoelectric material extends longitudinally along said direction z.

5. The sensorised braking device for a vehicle according to claim 1, wherein the piezoelectric material has a quadrangular configuration.

6. The sensorised braking device for a vehicle according to claim 1, wherein one or more extensions of a second electrode consist of a single extension that extends along said direction z.

7. The sensorised braking device for a vehicle according to claim 1, wherein one or more extensions of a second electrode consist of two extensions that extend along said direction Z.

8. The sensorised braking device for a vehicle according to claim 1, wherein the electric circuit is interposed between said support plate and said block of friction material and said at least one sensor is interposed between said electric circuit and said block of friction material.

9. The sensorised braking device for a vehicle according to claim 1, wherein the piezoelectric material is piezoceramic.
